(19) United States
(12) Patent Application Publication
(10) Pub. No.: US 2003/0139065 A1
(43) Pub. Date: Jul. 24, 2003

(54) Method for scaling down thickness of ONO film with remote plasma nitridation

(76) Inventor: Tzung-Ting Han, Ilan City (TW)

Correspondence Address: SUPREME PATENT SERVICES, POST OFFICE BOX 2339, SARATOGA, CA, 95070, US

(21) Appl. No.: 10/054,450

(22) Filed: Jan. 18, 2002

(51) Int. Cl. H01L 21/302; H01L 21/461; H01L 21/31; H01L 21/469

(52) U.S. Cl. 438/786; 438/738

(57) ABSTRACT

A method for scaling down thickness of ONO film with remote plasma nitridation, the method includes the acts of forming a substrate; form a first oxide layer on the substrate; nitrogenizing the oxide layer under the ONO film to form a nitridation layer; forming a nitride layer on the nitridation layer; and forming a second oxide layer on the nitride layer.

### FIELD OF THE INVENTION

The present invention relates to a method for scaling down the thickness of ONO film, and more particularly to a method to decrease the thickness of ONO film with remote plasma nitridation (RPN) to increase the oxidation resistance of Si₃N₄ in ONO film in the formation of top oxide. BACKGROUND OF THE INVENTION

The MONOS memory in the nonvolatile memory device has a laminated structure of metal/oxide/nitride/oxide/semiconductor. When the silicon-based substrate is exposed to the air, a thin oxidation is formed on the substrate, which is usually called as natural oxidation layer. A capacitor film is able to be formed on the natural oxidation layer and a Si₃N₄ layer is thus able to be formed on the natural oxidation layer. However, in order to remove the weak spot on the SiO₂ layer, an oxidation has to be formed on the Si₃N₄ layer, which is called as ONO (oxide/nitride/oxide).

The Floating Gate Cell in the nonvolatile memory device has an inter poly dielectric embedded therein to isolate the floating gate and other electrodes and that is why the inter poly dielectric has to be defect free as possible to prevent a leak in electric current. It is noticeable that to scale down the inter poly dielectric in the nonvolatile memory device is quite important, because the scaling down to the inter poly dielectric is able to increase the coupling ratio and the power consumption. Using the laminated ONO structure is able to allow the embedded inter poly dielectric to increase its prevention ability in electric current leakage and to increase its critical collapse voltage.

Within the sandwiched structure of the ONO, the nitride layer is used to store the electron. Therefore, the electron is able to be stored in the nitride layer by means of discrete trap and functions as nonvolatile memory device. In order to decrease power consumption and to have better operation speed, it is necessary to decrease the thickness of ONO in the SONOS and MONOS element. Accordingly, the quality of the ONO film is crucial in the nonvolatile memory device.

In the modern ONO film technology, there are two major drawbacks.

The first one is the low oxidation resistance caused by the overly thin nitride layer in the oxide layer on the ONO structure makes the reduce to the thickness of the ONO impossible, which limits the development of this technology.

The other drawback is that because the material difference in the SiO₂ and Si₃N₄ in the ONO structure, a low quality of transition layer is formed, which lowers the quality of the ONO film.

To overcome the shortcomings, the present invention intends to provide an improved method to decrease the thickness of ONO film with remote plasma nitridation (RPN) to mitigate or obviate the aforementioned problems.

### SUMMARY OF THE INVENTION

The primary objective of the invention is to provide a method to scale down the ONO film so as to increase the oxidation resistance of the Si₃N₄ in the ONO film when the top oxide is formed.

In order to achieve the foregoing objectives, the method includes the steps such as forming a substrate. After the substrate is formed, a first oxide layer is formed on the substrate. Then, using the nitridation technique to form a nitride layer is the third step. The fourth step is to form a Si₃N₄ layer on the nitride layer. Thereafter, a second oxide layer is formed on the Si₃N₄ layer.

Other objects, advantages and novel features of the invention will become more apparent from the following detailed description when taken in conjunction with the accompanying drawings.

### BRIEF DESCRIPTION OF THE DRAWINGS

FIG. 1 is a flow chart of the method in accordance with the present invention; and

FIGS. 2A to 2E are cross sectional views of the structure formed in accordance with the method in FIG. 1.

### DETAILED DESCRIPTION OF THE INVENTION

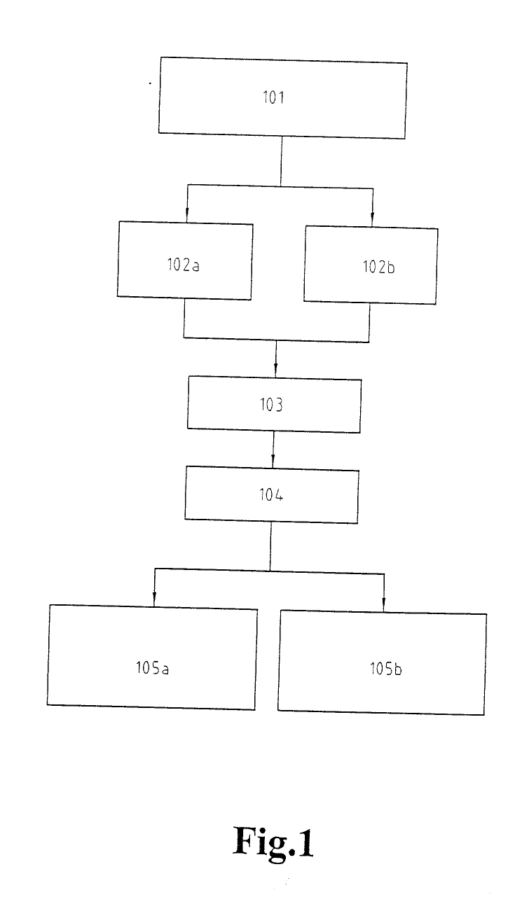

With reference to FIG. 1, the method for scaling down thickness of ONO film with remote plasma nitridation includes the following steps.

Step 101 is to form a substrate or a floating gate. The substrate may be made of Si, amorphous-Si or poly-Si.

Step 102(a) or 102(b) is to form an oxide layer on the substrate by means of CVD (chemical vapor deposition) or thermal oxidation or on the floating gate by means of CVD (chemical vapor deposition) or thermal oxidation.

Step 103 is to nitrogenize the oxide layer under the ONO film by means of RPN (remote plasma nitridation) so as to form a nitridation layer.

Step 104 is to form a nitride layer on the nitridation layer by means of LPCVD (low pressure chemical vapor deposition).

Step 105(a) or 105(b) is to form an oxide layer on the nitride layer by CVD or by thermal oxidation to form the oxide layer on the nitride layer.

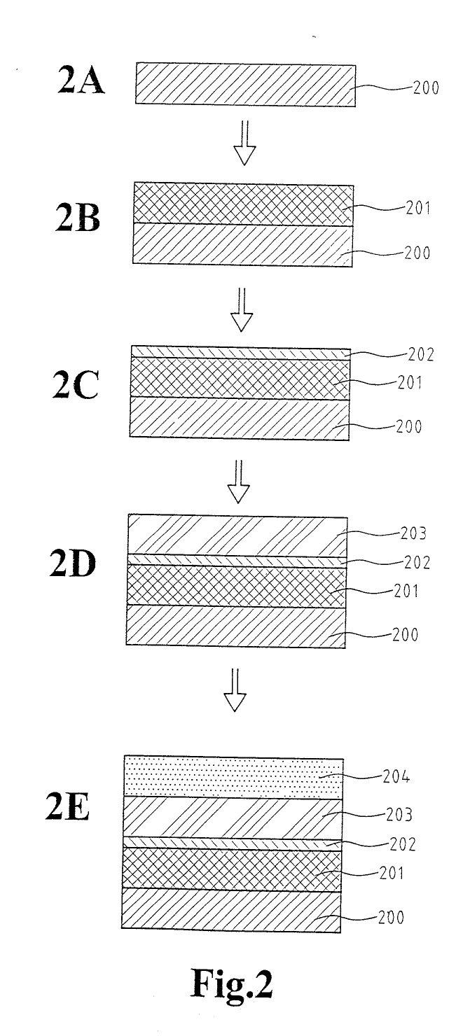

With reference to FIGS. 2A to 2E, it is first to provide a substrate 200 made of an material such as Si, amorphous-Si or poly-Si. After the substrate 200 is provided, a first oxide layer 201 is formed on the substrate 200 by CVD or thermal oxidation. Then, a nitridation layer 202 is formed on the first oxide layer 201, which is to nitrogenize a periphery of the first oxide layer 20, wherein the nitridation layer 202 is developed on the first oxide layer 201 by means of RPN (remote plasma nitridation) so as to increase the oxidation resistance capability in the formation of a top oxide on the Si₃N₄ in the ONO film. Thereafter, a nitride layer 203 is formed on the nitridation layer 202, which is using the LPCVD to deposit Si₃N₄ on the nitridation layer 202. The last step is to form a second oxide layer 204 on the nitride layer 203 by means of CVD or thermal oxidation.

It is to be noted that by means of RPN, the formation of the nitridation layer 202 is able to allow the nitride layer 203 to be scaled down so as to achieve the purpose of minimizing the thickness of ONO film.

Even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for scaling down thickness of ONO film with remote plasma nitridation, the method comprising the acts of:
forming a substrate;
form a first oxide layer on the substrate;
nitrogenizing the oxide layer under the ONO film to form a nitridation layer;
forming a nitride layer on the nitridation layer; and
forming a second oxide layer on the nitride layer.

2. The method as claimed in claim 1, wherein the substrate is made of a material selected from the group consisting of Si, amorphous-Si and poly-Si.

3. The method as claimed in claim 1, wherein the first oxide layer on the substrate is formed by means of chemical vapor deposition.

4. The method as claimed in claim 1, wherein the firs oxide layer on the substrate is formed by means of thermal oxidation.

5. The method as claimed in claim 1, wherein the nitridation layer is formed by remote plasma nitridation on the first oxide layer.

6. The method as claimed in claim 1, wherein the nitride layer is formed by low pressure chemical vapor deposition on the nitridation layer.

7. The method as claimed in claim 1, wherein the second oxide layer is formed by chemical vapor deposition.

8. The method as claimed in claim 1, wherein the second oxide layer is formed by thermal oxidation.

9. The method as claimed in claim 1, wherein the substrate is a floating gate.

10. A semiconductor structure to nitrogenize the oxide layer under the ONO film by remote plasma nitridation, the semiconductor structure comprising:
a substrate;
a first oxide layer formed on the substrate;
a nitridation layer, which is formed on the first oxide layer by nitrogenizing surface of the first oxide layer;
a nitride layer formed on the nitridation layer; and
a second oxide layer formed on the nitride layer.

11. The structure as claimed in claim 10, wherein the substrate is made of a material selected from the group consisting of Si, amorphous-Si and poly-Si.

12. The method as claimed in claim 10, wherein the first oxide layer on the substrate is formed by means of chemical vapor deposition.

13. The method as claimed in claim 10, wherein the firs oxide layer on the substrate is formed by means of thermal oxidation.

14. The method as claimed in claim 10, wherein the nitridation layer is formed by remote plasma nitridation on the first oxide layer.

15. The method as claimed in claim 10, wherein the nitride layer is formed by low pressure chemical vapor deposition on the nitridation layer.

16. The method as claimed in claim 10, wherein the second oxide layer is formed by chemical vapor deposition.

17. The method as claimed in claim 10, wherein the second oxide layer is formed by thermal oxidation.
